(19) United States
(12) Patent Application Publication
(10) Pub. No.: US 2012/0256004 A1
(43) Pub. Date: Oct. 11, 2012

(54) SELECTIVELY ENABLED RFID TAG

(75) Inventor: Gary L. Moore, JR., Dayton, OH (US)

(73) Assignee: Redbud Systems, LLC, Dayton, OH (US)

(21) Appl. No.: 13/313,211

(22) Filed: Dec. 7, 2011

Related U.S. Application Data
(63) Continuation-in-part of application No. 13/081,980, filed on Apr. 7, 2011.

(51) Int. Cl. G06K 19/077; H05K 13/04

(52) U.S. Cl. 235/492; 29/601

(57) ABSTRACT

A RFID tag including an antenna positioned on a first substrate and a chip positioned on a second substrate. The tag is manually shiftable from a first state to a second state, wherein one of the first or second states is a state in which the chip and the antenna are electrically coupled, and wherein the other one of the first or second states is a state in which the chip and the antenna are electrically uncoupled.

This application is a continuation-in-part of U.S. application Ser. No. 13/081,980, entitled SELECTIVELY ENABLED RFID TAG filed on Apr. 7, 2011, the entire contents of which are incorporated by reference herein.

The present invention is directed to an RFID tag, and more particularly, to a selectively enabled RFID tag.

### BACKGROUND

RFID tags are used to transmit information, data or the like when exposed to an appropriate wavelength and/or frequency of electromagnetic radiation. RFID tags are becoming increasingly more ubiquitous and are incorporated in a wide variety of cards, devices and the like, and tags may be used to store confidential and/or personal information. Accordingly, when a RFID tag passes within the range of an RFID reader, the RFID reader may be able to extract personal and/or confidential information from the RFID tag without the consent of the RFID tag owner.

### SUMMARY

In one embodiment, the present invention is an RFID tag which is selectively enabled to minimize the loss of personal, confidential or other information. In particular, in one embodiment the invention is a RFID tag including an antenna positioned on a first substrate and a chip positioned on a second substrate. The tag is manually shiftable from a first state to a second state, wherein one of the first or second states is a state in which the chip and the antenna are electrically coupled, and wherein the other one of the first or second states is a state in which the chip and the antenna are electrically uncoupled.

### BRIEF DESCRIPTION OF DRAWINGS

FIG. 1 is a top schematic view of one embodiment of the RFID tag of the present invention;

FIG. 2 is a schematic cross-section of the RFID tag of FIG. 1, with the chip and antenna out of electrical contact;

FIG. 3 illustrates the RFID tag of FIG. 2, with the chip and antenna in electrical contact;

FIG. 4 is a top perspective view of the RFID tag of FIG. 1, with various portions of certain layers of the RFID tag cut away;

FIG. 5 is a top view of an alternate embodiment of the RFID tag of the present invention;

FIG. 6 is a schematic cross section of the tag of FIG. 6, with the chips and antenna out of electrical contact;

FIG. 7 is a schematic cross section of another alternate embodiment of the RFID tag of the present invention, shown in its disabled state;

FIG. 8 is a schematic cross section of the RFID tag of FIG. 7, shown in its enabled state; and

FIG. 9 is a side schematic view of a substrate carrying a plurality of chips thereon.

### DETAILED DESCRIPTION

FIGS. 1-4 illustrate a first embodiment of the RFID tag 10 of the present invention. The illustrated RFID tag 10 includes an antenna 12 which is tuned to a specific frequency and/or wavelength of electromagnetic radiation. The RFID tag 10 further includes a chip 14 which can take the form of a microchip, an integrated circuit, CMOS circuitry, or other logic circuitry or the like. The RFID tag 10 further includes an enclosure, laminate or outer casing 16.

In the illustrated embodiment, both the antenna 12 and chip 14 are substantially embedded in, and/or carried within, the outer casing 16 which can form the majority of the volume of the RFID tag 10. The outer casing 16, in the illustrated embodiment, also forms the outer surfaces of the RFID tag 10 to seal and protect the antenna 12 and chip 14. The outer casing 16 may be generally continuous, particularly across its outer surfaces, to protect the internal components. The casing 16 can be made of a wide variety of materials such as, for example, polyvinyl chloride acetate, although the casing 16 can be made of a wide variety of plastic, polymer or other suitably protective and flexible materials. The casing 16 can be made of translucent, transparent and/or opaque materials, as desired. However, in the embodiment of FIG. 1, the casing 16 is illustrated as being transparent for illustrative purposes.

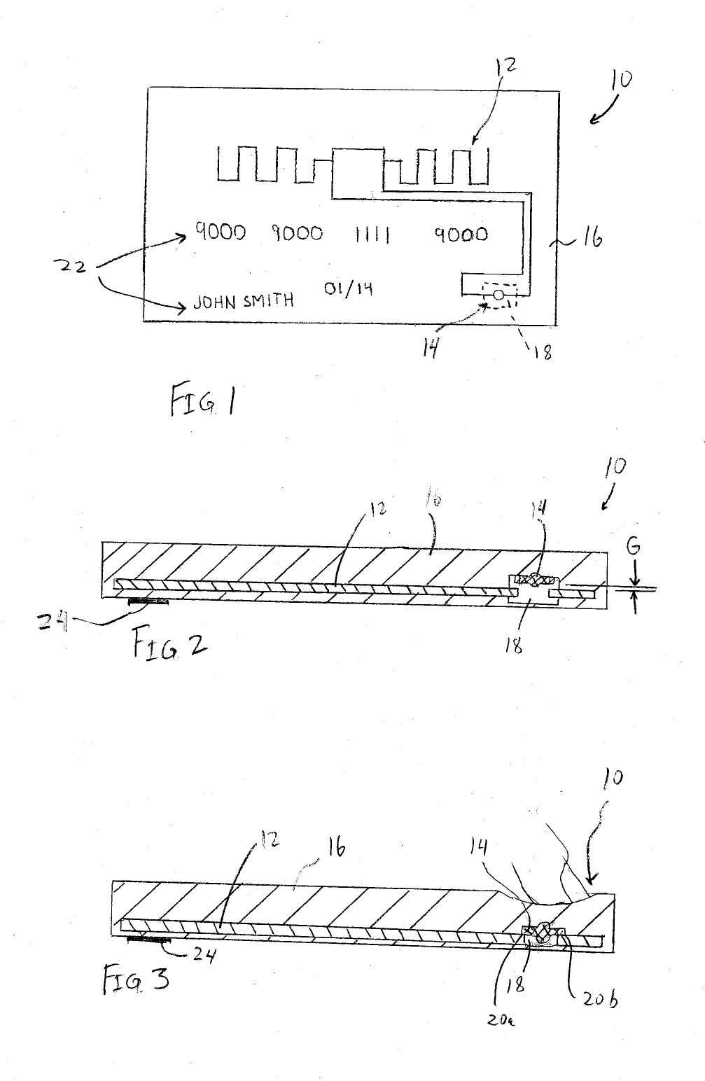

In the illustrated embodiment, both the antenna 12 and the chip 14 are generally flat and planar, and are positioned out-of-plane relative to each other in the configuration shown in FIG. 2. In addition, in the illustrated embodiment, a void 18 is positioned in the casing 16, and located at or adjacent to the chip 14. For example, in the embodiment shown in FIG. 2, the void 18 is positioned below the chip 14, and extends downwardly to (and slightly below) the plane of the antenna 12. However, the void 18 can be positioned in any wide variety of locations within the tag 10/casing 16, including above the chip 14, between the chip 14 and the antenna 12, below the chip 14, and combinations thereof.

In the state shown in FIG. 2, the chip 14 is biased out-of-plane, and therefore out of electrical contact, with the antenna 12. Thus, in FIG. 2 the RFID tag 10 is in its disabled state or condition and cannot be operated as an RFID tag or device. When it is desired to enable the tag 10 for RFID operation, portions of the RFID tag 10 positioned above/below the void 18 are manually pressed and deformed, as shown in FIG. 3. In this manner, when the user manually presses on the appropriate location of the card 10, the void 18 and outer casing 16 are elastically deformed and the chip 14 is pressed into contact with the antenna 12, thereby moving or shifting the tag 10 to its enabled position or state. The outer casing 16 therefore has, in the illustrated embodiment, sufficient flexibility to be manually deflected to cause the chip 14 to engage the antenna 12 (and/or vice versa). In one embodiment, the appropriate surface (i.e. top surface in the illustrated embodiment, in the area of the chip 14/void 18 shown in FIG. 1) of the outer casing 16 may include indicia indicating where a user is to press to enable the card (i.e. a symbol, or text such as “press here to enable,” etc.).

When the RFID tag 10 is enabled, the RFID tag 10 may be exposed to electromagnetic radiation, such as that emitted by a RFID reader. The electromagnetic radiation may be at or substantially at the particular frequency/wavelength to which the antenna 12 is tuned. The antenna 12 collects energy from the electromagnetic waves to induce a charge therein, which is in turn communicated to the chip 14. Once the chip 14 receives a sufficient charge (and in some cases, after an appropriate time delay, such as about 0.5 seconds in one case), the chip 14 generates a data pulse that includes data or information, such as alphanumeric data, and in some cases alphanumeric data corresponding to a unique identifier of the chip 14. The data pulse is then provided to the antenna 12, which uses the energy provided from the chip 14 (or previously stored in the antenna 12) to broadcast the data associated with the chip 14 back outward such that it can be, for example, received by the RFID reader. In this manner, when enabled, the RFID tag 10 can respond to output from an RFID reader in a standard manner for RFID tags/devices.

When it is desired to disable the tag 10, the user removes his or her finger from the tag 10/casing 16, thereby removing the manual pressure. The tag 10/casing 16 then elastically returns to its original, undeformed disabled state, as shown in FIG. 2. In this manner, a user can control when the tag 10 is enabled and capable of emitting a signal, and when the tag 10 is disabled, thereby providing increased security and control.

As noted above, in the illustrated embodiment the chip 14 is positioned out-of-plane with the antenna 12 when the chip 14 is in its disabled position. Thus, as can be seen in FIG. 2, the tag 10 has a gap G extending in a direction of perpendicular to the plane of the chip 14/antenna 12/tag 10 when the tag 10 is in its disabled position, the gap G extending in the direction of travel of the chip 14. The gap G should be sufficiently large to ensure the RFID tag 10 can be effectively disabled and the antenna 12 and chip 14 moved out of effective electrical contact/communication. In contrast, when the chip 14 is pressed into contact with the antenna 12, the chip 14 makes two spaced points of contact 20a, 20b with the antenna 12 (FIG. 3). Accordingly, under this arrangement, the chip 14 makes two spaced points of contact 20a, 20b when enabled, and provides two separate and discrete open circuits when disabled, which helps to ensure the tag 10 is not accidentally enabled when it is desired to be disabled (and vice versa).

As noted above, the void 18/gap G should be large enough to ensure that the chip 14 remains decoupled from the antenna 12 when desired. However, the void 18/gap G should be sufficiently small that the casing 16 can be deformed without requiring undue manual pressure, and so the chip 14 can repeatedly accurately engage the antenna 12. In addition, in the illustrated embodiment, the chip 14 is positioned immediately above the antenna 12/void 18 such that the chip 14 is moved translationally (i.e. as opposed to pivotally) when the chip 14 is moved into its enabled position to more easily accommodate typical manual pressure. The antenna 12/void 18/chip 14 may also need to be precisely shaped and positioned to ensure proper contact is made when desired.

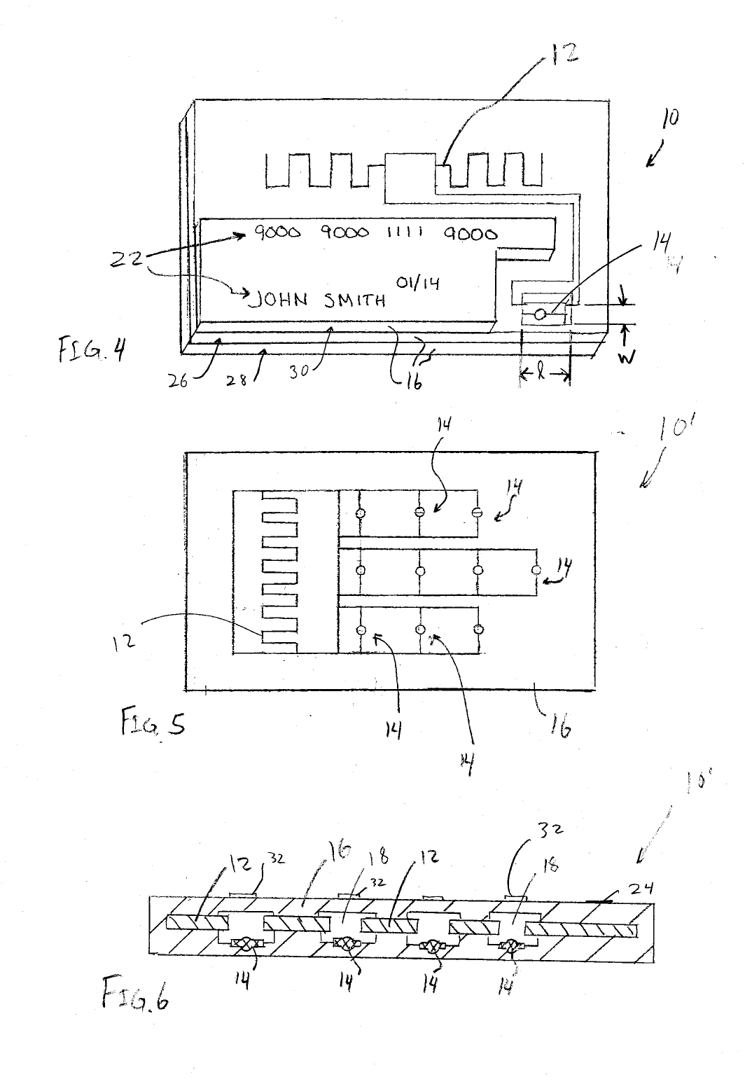

As can be seen in FIG. 4, the chip 14 may be generally flat and planar within the chip plane and have a length l and a width w within the chip plane. The size of the gap G is, in one case, less than either the width w or length l of the chip 14 such that the chip 14 is required to move a relatively small distance between the enabled and disabled position. In one particular case, the gap G is less than about ⅛″, and in another embodiment is less than about 1/16″.

The configuration disclosed herein, in which the chip 14 is out of plane, or out of alignment, with the antenna 12, and moved into contact with the antenna 12 (or vice versa) also provides certain manufacturing advantages. In particular, a plurality of partially completed RFID tags 10 can be manufactured with a particular type of antenna 12, and a plurality of chips 14 can be separately manufactured and/or stored. When it is desired to complete the RFID tag 10, a chip is 14 selected and mated with an antenna 12 to form a tag 10. The separate manufacturing and storage of antennae 12 and chips 14, and their ability to be joined together at the time of manufacture, enables modular manufacturing for greater efficiency and flexibility.

FIG. 4 illustrates one embodiment of the tag 10, with portions of various layers thereof cut-away to show the various sub-layers, and which includes the antenna plane 26, chip plane 28, and upper plane 30, each of which has portions cut-away for illustrative purposes. In the embodiment of FIG. 4 (in contrast to FIGS. 2 and 3), the chip 14 is positioned below the antenna 12. In this case, the antenna 12 (or at least parts of the antenna 12 positioned adjacent to the chip 14) may be deflectable out-of-plane and into contact with the chip 14 to electrically couple the antenna 12 and chip 14. In actuality, in both the embodiment of FIGS. 2 and 3 (wherein the chip 14 is positioned above the antenna 12) and the embodiment of FIG. 4 (wherein the chip 14 is positioned below the antenna 12), both the chip 14 and antenna 12 (or portions thereof) may be deflected somewhat out-of-plane upon the application of manual pressure.

In some cases, however, it may be desired to limit the deflection of the antenna 12, as excessive deflection of the antenna 12 could adversely effect its reception/broadcast properties and capabilities. The embodiments disclosed herein in which the chip 14, and/or portions of the antenna 12 positioned adjacent to the chip 12, are deflected (as opposed to, for example, deflection of larger portions of the antenna) helps to limit deflection of the antenna 12 and ensure proper operation thereof.

In addition, the embodiments shown in FIGS. 1-4 show the RFID tag 10 biased into a position in which the chip 14 and antenna 12 are electrically decoupled. However, the biasing state of the RFID tag 10 can be reversed. In particular, the chip 14 and antenna 12 can be biased into electrical contact, in which case manual pressure can be utilized to move the chip 14 and antenna 12 out of electrical contact to disable the RFID tag 10.

As shown in FIGS. 1 and 4, the RFID tag 10 may take the form of a financial card, such as a credit card, debit card, pre-paid card, gift card, etc, or an identification card, security card, or the like. In this case, then, the RFID tag 10 may carry various information 22 printed on its front surface thereof, such as an identification of the card owner, card expiration date, card number, etc. The card/RFID tag 10 can have relatively standard dimensions for a credit card, debit card or the like, such as having, in one case, a length of about 3½″ (or less than about 4″), a width of about 2⅛″ (or less than about 3″) and a thickness of less than about ¼″, or less than about ⅛″. In addition, a magnetic strip 24 which embodies the information carried on the front of the card 10, and/or additional information, can be carried on the card 10 and is readable by a magnetic strip reader.

In an alternate embodiment, as shown in FIGS. 5 and 6, the tag 10′ includes an antenna 12 and a plurality of chips 14 (ten chips 14 in the illustrated embodiment). Each chip 14 can be positioned out-of-plane with the antenna 12 (or vice-versa), and be manually deflectable to place the chip 14 into (or out of) electrical connection with the antenna 12, thereby enabling (or disabling) the particular chips 14. As shown in FIG. 6, in the illustrated embodiment each chip 14 is positioned below the antenna 12, although each chip 14 can be positioned above the antenna 12, or positioned in other configurations to enable selective enablement thereof. In some cases, some chips 14 can be positioned above the antenna 12, and other positioned below the antenna 12.

In this embodiment, each chip 14 may include indicia 32 associated therewith positioned on the outer surface of the casing 12. For example, each chip 14 may include a unique numerical identifier (0-9) associated therewith. The identifiers/indicia 32 may also take the form of alphabetical symbols, alphanumeric symbols or other indicia.

Each chip 14 may include a unique identifier associated therewith such that when that chip 14 is electrically coupled to the antenna 12, the chip 14 causes the antenna 12 to broadcast an identifier or data stream for that chip 14 that is unique relative to other chips 14 on the card 10′ (or relative to any other chip 14, even on other cards/tags 10, 10′). In this manner, the tag 10′ of FIGS. 5 and 6 may be utilized by a user to transmit a stream of data to a RFID card reader, such as a pin or other security code. The tag 10′ can also be used as a security device such that, for example, a user may be required to enter a particular code before being granted access to a particular area, before a financial transaction is completed, etc.

The tag 10′/chips 14 may also be configured to transmit a particular signal when more than one of the chips 14 are enabled. For example, the chips 14 associated with the numbers “1” and “3” can be enabled at the same time, which may cause the tag 10′ to emit a signal indicating those chips 14 have been enabled. The emitted signal could, in some cases, be different than the signal associated with simply pressing “1” and “3” in order, thereby exponentially increasing the number of signals capable of being emitted due to the large number of chip combinations. This configuration also enables the use of multiple chips 14 for transmitting information in a wide variety of manners without the use of any external switches, circuitry or memory (besides that included in the chips 14) or an external power source or the like. It should be understood that, in one embodiment, the RFID tag 10, 10′ (as well as the tag 10″ described below) is passive and lacks any power source for storing power beyond a transient basis (i.e. the tag lacks a battery or the like).

The embodiments disclosed above show a single antenna 12 with a single chip 14, and a single antenna 12 with multiple chips 14. The RFID tag may also include multiple chips 14 with multiple antennas 12. In this case, each antenna 12 may be located in its own plane, or share a plane with other antennas 12. This embodiment provides greater flexibility as to the range of transmission and reception of data.

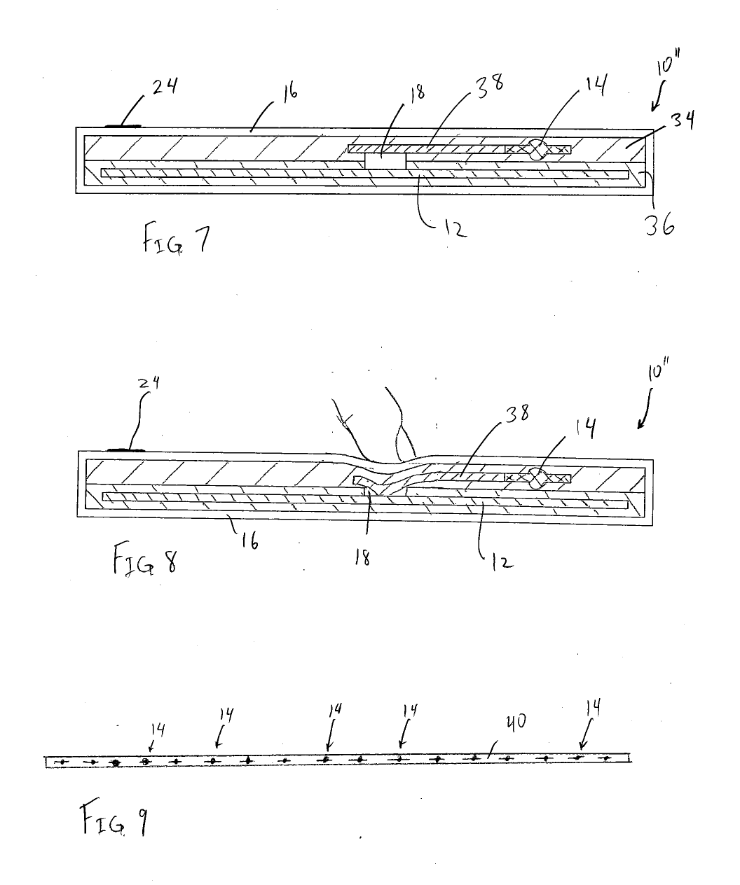

FIG. 7 illustrates a further alternate embodiment of the RFID tag 10″. In this case the chip 14 may be carried on, or positioned on/within, a substrate 34, and the antenna 12 is carried on, or positioned on/within, a substrate 36. The materials and nature of the substrates 34, 36 can vary, but in one embodiment each substrate 34, 36 is made of a polymer material, such as polyvinyl, and may have a thickness of between about 0.5 mils and about 3 mils. A conductive component 38 is positioned generally between the substrates 34, 36, and permanently electrically coupled to the chip 14. The conductive component 38 can be made of or coated with a variety of electrically conductive materials, such as metal, including but not limited to aluminum, copper, silver or gold.

In the illustrated embodiment the RFID tag 10″ includes a void or gap 18 therein positioned adjacent to the antenna 12 and conductive component 38. In this manner, when manual pressure is applied at or in the area of the void 18/conductive component 38, the conductive component 38 is deflected into contact with the antenna 12 to electrically connect the chip 14 and antenna 16 and enable the tag 10″ (FIG. 8). When the manual pressure is removed, the chip 10″ elastically returns to the position shown in FIG. 7.

Of course, the tag 10″ shown in FIGS. 7 and 8 can be arranged in a variety of manners besides the particular configuration shown therein. For example, the conductive component 38 can be positioned in one or both of the substrates 34, 36, or between the substrates 34, 36, or be permanently electrically coupled to either the antenna 12 instead of the chip 14, and the void 18 can be positioned at various different locations.

Each of the substrates 34, 36 can be a physically discrete substrate which are positioned immediately adjacent to each other, and generally parallel, within the outer casing 16. In one case the substrates 34, 36 are made of separate pieces of material and are not pivotally joined, or joined along any crease line or the like. This arrangement helps to ensure physical/electrical isolation between the antenna 12 and chip 14 when desired, and also provides ease of manufacturing. In particular, as shown in FIG. 9, a plurality of chips 14 can be formed on a larger chip substrate sheet 40. An antenna substrate sheet (not shown), carrying a plurality of antennas, can similarly be formed. The substrate sheets can then be separated or die cut to isolate individual antennas 12/chips 14, or groups of antennas 12/chips 14, as desired.

After the individual chips 14/antennas 12 are separated, they can be assembled together in to form the tag 10″ shown in FIGS. 7 and 8 (or other figures herein) by, for example, forming the void 18, placing the conductive component 38 in the appropriate position, and positioning the assembly within the outer casing 16. This system enables bulk/batch manufacturing of chips 14 and antennas 12 as desired.

Although FIGS. 7-9 specifically illustrate an embodiment in which the chip 14 and antenna 12 are on differing substrates/planes, it should be understood that the tags 10, 10′ shown in FIGS. 1-6 may also be constructed in the same or a similar manner in which the chip(s) 14 and antenna(s) 12 are on differing substrates/planes. Moreover, the features and functionalities of the tag 10 shown in FIGS. 1-4 may also generally be implemented in the tag 10′ shown in FIGS. 5 and 6 and the tag 10″ shown in FIGS. 7 and 8. Conversely, the features and functionalities of the tag 10′ shown in FIGS. 5 and 6 may also generally be implemented in the tag 10 shown in FIGS. 1-4 and the tag 10″ shown in FIGS. 7 and 8, and the features and functionalities of the tag 10″ shown in FIGS. 7 and 8 may also generally be implemented in the tag 10 shown in FIGS. 1-4 and the tag 10′ shown in FIGS. 4 and 5.

The tag 10, 10′ is described herein as an “RFID” tag, but it should be understood that this does not necessarily mean that the RFID tags 10, 10′, 10″/antenna 12 are restricted for use at RF frequencies. In particular, following industry convention, the RFID tag 10, 10′/antenna 12 can be utilized in conjunction with any of a wide variety of frequencies of electromagnetic energy ranging, in one case, between about 125 kHz and about 900 GHz. It should also be understood that the various features and functionalities of the various embodiments described herein may be combined and used in various manners.

Having described the invention in detail and by reference to certain embodiments, it will be apparent that modifications and variations thereof are possible without departing from the scope of the invention.

What is claimed is:

1. A RFID tag comprising:
an antenna positioned on a first substrate; and
a chip positioned on a second substrate, wherein said tag is manually shiftable from a first state to a second state, wherein one of said first or second states is a state in which said chip and said antenna are electrically coupled, and wherein the other one of said first or second states is a state in which said chip and said antenna are electrically uncoupled.

2. The tag of claim 1 wherein said first and second substrates are fixed in a position in which they are generally parallel and positioned immediately adjacent to each other.

3. The tag of claim 1 wherein said first and second substrates are each separate and discrete pieces of material.

4. The tag of claim 1 further comprising an outer casing positioned about and generally surrounding said first and second substrates.

5. The tag of claim 1 further comprising a conductive element, wherein said conductive element is manually movable to cause said tag to shift between said first and second states.

6. The tag of claim 5 wherein said conductive element is configured to extend from said first substrate to said second substrate when said tag is in one of said first or second states, and is configured to not extend from said first substrate to said second substrate when said tag is in the other of said first or second states.

7. The tag of claim 1 wherein at least one of said chip or said antenna is movable into and out of direct electrical contact with the other one of said chip or antenna to cause said tag to shift between said first and second states.

8. The tag of claim 7 wherein said outer casing, said first substrate and said second substrate are sufficiently flexible to be manually deflectable and sufficiently elastic to return to their original shapes when said manual deflection forces are removed.

9. The tag of claim 1 wherein said tag is biased into said first state in which said chip and said antenna are electrically uncoupled, and wherein said tag is manually shiftable to said second state in which said chip and said antenna are electrically coupled.

10. The tag of claim 9 wherein said tag is configured such that when a manual force causing said tag to be in said second state is removed, said tag automatically returns to said first position.

11. The tag of claim 1 wherein said antenna is tuned to a particular frequency of electromagnetic energy, and wherein said chip is configured such that when said chip and antenna are electrically coupled and said tag is exposed to electromagnetic energy at or substantially at said particular frequency, said chip becomes electrically charged.

12. The tag of claim 11 wherein said antenna is tuned to electromagnetic energy having a frequency of between about 125 kHz and about 900 GHz.

13. The tag of claim 11 wherein said chip is configured such that, after becoming sufficiently electrically charged, said chip causes said antenna to transmit an output signal associated with said chip.

14. A RFID tag comprising:
an outer casing;
an antenna positioned within said outer casing; and
a chip positioned within said outer casing and out of plane relative to said antenna, wherein said tag is manually shiftable from a first state to a second state, wherein one of said first or second states is a state in which said chip and said antenna are electrically coupled, and wherein the other one of said first or second states is a state in which said chip and said antenna are electrically uncoupled.

15. A RFID tag comprising:
an outer casing;
an antenna positioned on a first substrate in said outer casing; and
a chip positioned on a second substrate in said outer casing, wherein at least part of an outer surface of said RFID tag is manually movable to cause said chip and said antenna to be electrically coupled or to cause said chip and said antenna to be electrically uncoupled.

16. A RFID tag comprising:
an antenna;
a chip; and
a generally flexible outer casing positioned generally around said antenna and said chip, wherein said tag is manually shiftable from a first state to a second state, wherein one of said first or second states is a state in which said chip is electrically coupled to said antenna, and wherein the other one of said first or second states is a state in which said chip is electrically uncoupled from said antenna.

17. The tag of claim 16 wherein said chip is positioned on a first substrate and said chip is positioned on a second substrate that is made from a separate piece of material than said first substrate.

18. A method for making a RFID tag comprising:
accessing a first substrate with an antenna thereon;
accessing a second substrate with chip thereon; and
positioning said antenna and said chip to form a tag that is manually shiftable from a first state to a second state, wherein one of said first or second states is a state in which said chip and said antenna are electrically coupled, and wherein the other one of said first or second states is a state in which said chip and said antenna are electrically uncoupled.

19. The method of claim 18 further comprising the steps of accessing an antenna substrate having a plurality of antennas thereon, cutting said antenna substrate to form said first substrate, accessing an chip substrate having a plurality of chips thereon, and cutting said antenna substrate to form said second substrate.

20. The method of claim 18 wherein said first and second substrates are separate pieces of material.
